(19) United States
(12) Patent Application Publication
(10) Pub. No.: US 2026/0135473 A1
(43) Pub. Date: May 14, 2026

(54) APPARATUS AND METHOD FOR PROTECTING POWER CONVERSION DEVICE

(71) Applicants: Hyundai Motor Company, Seoul (KR); Kia Corporation, Seoul (KR)

(72) Inventors: Hyun Woo Jung, Hwaseong (KR); Kyung Woo Lee, Hwaseong (KR); Su Woong Eo, Hwaseong (KR); Dae Un Sung, Hwaseong (KR); Sang Hyun Moon, Hwaseong (KR)

(21) Appl. No.: 19/387,323

(22) Filed: Nov. 12, 2025

(30) Foreign Application Priority Data
Nov. 14, 2024 (KR) 10-2024-0162005
Oct. 1, 2025 (KR) 10-2025-0143454

(51) Int. Cl. H02M 1/32; B60L 3/00; H05K 7/20

(52) U.S. Cl. CPC H02M 1/327; H05K 7/209; H05K 7/20945; B60L 3/003; B60L 2240/525

(57) ABSTRACT

Disclosed are a protection apparatus and method for estimating thermal stress of a power conversion device and preventing damage thereto using a virtual sensor based on a reduced-order model. Thermal stress applied to a power conversion device in a vehicle is estimated using virtual sensor software without the need for any hardware sensors. When the estimated thermal stress reaches a threshold value, a control signal is output to prevent damage to the power conversion device, which is also used for device condition monitoring and failure prediction.

This application claims, under 35 U.S.C. § 119(a), the benefit of Korean Patent Application No. 10-2024-0162005, filed Nov. 14, 2024, and Korean Patent Application No. 10-2025-0143454, filed Oct. 1, 2025, the entire contents of which are incorporated herein by reference.

### BACKGROUND

### (a) Technical Field

The present disclosure relates to an apparatus and method for protecting a power conversion device from damage and, more particularly, to a protection apparatus and method for estimating thermal stress of a power conversion device, and preventing damage thereto, using a virtual sensor, based on a reduced-order model.

### (b) Background

Power conversion devices such as inverters and converters are devices that convert electric power to meet desired power conditions, such as voltage, current, and frequency, and are essential technological elements in modern electrical, electronic, and energy systems. Semiconductor devices, such as an insulated gate bipolar transistor (IGBT), a metal-oxide-semiconductor field effect transistor (MOSFET), and a diode, are included in such power conversion devices as key components.

Power conversion devices generate electromagnetic interference (EMI) due to high-frequency switching, and electromagnetic compatibility (EMC) needs to be considered. In order to prevent unnecessary emission of electromagnetic waves from power conversion devices and to ensure immunity, that is, to prevent power conversion devices from being affected by external electromagnetic waves, the structure, material and layout of the package are designed in a manner referred to as EMC packaging.

The main purposes of EMC packaging are to suppress noise generated from power conversion devices, to provide shielding against external electromagnetic waves, and to ensure integrity during transmission of high-frequency signals and power.

Various packaging methods may be employed. There is a shielding method of applying a metal cap, a metal film, or a conductive film to the surface of a power conversion device to block external electromagnetic waves and suppress emission of internal noise. There is a grounding structure reinforcement method of placing multiple ground pads or ground planes inside the package to minimize the return path of noise current.

Power conversion devices are highly sensitive to temperature (overheating). When temperature rises excessively, switching losses increase, and leakage current rises, leading to device failure. Power conversion devices may generate heat due to resistive losses and switching losses under operating conditions. As a result, thermal stress may be generated inside the device due to the temperature gradient between a heat-generating chip and the surrounding area and a difference in coefficient of thermal expansion therebetween. Repeated increases and decreases of thermal stress may cause mechanical damage to the electromagnetic compatibility (EMC) packaging of power conversion devices, leading to wire bonding delamination, which is one of the major failure causes of power conversion controllers employing discrete power conversion devices.

Protective devices for preventing damage to power conversion devices comprise a cooling device using a heat sink, a fan, and liquid cooling, and a device that connects a temperature sensor such as an NTC thermistor to a power conversion device to monitor temperature in real time or to limit current before temperature rises, thereby protecting the device from overcurrent.

As conventional technology for protecting power conversion devices, Korean Patent Laid-Open Publication No. 10-1999-0012878 discloses technology for protecting a device and improving stability of the device in the event of short circuit. When the ambient temperature and the temperature of the device rise, compensation may be performed using a current source, thereby achieving stable operation under varying temperature.

However, even if the chip temperature remains constant during operation under initial low-temperature conditions, thermal stress is significantly applied to the EMC part due to the temperature difference between the chip and the surrounding area, which may result in damage to the power conversion device.

### SUMMARY

Accordingly, embodiments are directed to an apparatus and method for protecting a power conversion device that substantially obviate one or more problems due to limitations and disadvantages of the related art.

An aspect of the present disclosure is to provide an apparatus and method for protecting a power conversion device by estimating thermal stress of the power conversion device without using a hardware sensor.

Another aspect of the present disclosure is to provide an apparatus and method for protecting a power conversion device by controlling an output from the power conversion device in real time.

However, the aspects to be accomplished by the embodiments are not limited to the above-mentioned aspects, and other aspects not mentioned herein will be clearly understood by those skilled in the art from the following description.

Additional advantages, aspects, and features of the disclosure will be set forth in part in the description which follows and in part will become apparent to those having ordinary skill in the art upon examination of the following or may be learned from practice of the disclosure. The aspects and other advantages of the disclosure may be realized and attained by the structure particularly pointed out in the written description and claims hereof as well as the appended drawings.

An apparatus for protecting a power conversion device according to the present disclosure for accomplishing the above aspects may include a measured information provider configured to provide actually sensed data, a system information provider configured to provide system variable data, a virtual sensor configured to input the actually sensed data and the system variable data to a reduced-order model, generated in a polynomial form through learning based on accumulated data, to calculate a maximum stress of the power conversion device, and a controller configured to compare the maximum stress of the power conversion device calculated by the virtual sensor with a threshold value and to selectively output a control signal for prevention of damage to the power conversion device based on a result of comparison.

In the apparatus for protecting a power conversion device according to the present disclosure, the actually sensed data may include data on at least one of an ambient temperature of the power conversion device or a temperature of a coolant.

In the apparatus for protecting a power conversion device according to the present disclosure, the system variable data may include information about at least one of a heat generation amount of the power conversion device or whether to cool the power conversion device.

In the apparatus for protecting a power conversion device according to the present disclosure, the control signal for prevention of damage to the power conversion device may adjust a heat generation amount of the power conversion device through derating.

In the apparatus for protecting a power conversion device according to the present disclosure, the control signal for prevention of damage to the power conversion device may increase heat dissipation through cooling control to prevent application of excessive stress.

In the apparatus for protecting a power conversion device according to the present disclosure, the reduced-order model may employ a regression model configured to numerically output a result value for a given input.

In the apparatus for protecting a power conversion device according to the present disclosure, the regression model may be any one of an artificial intelligence model, a response surface model, and a polynomial regression model.

In the apparatus for protecting a power conversion device according to the present disclosure, the reduced-order model may receive an initial temperature value and a power value of a predetermined portion of the power conversion device, and may output a maximum stress value of the predetermined portion.

In the apparatus for protecting a power conversion device according to the present disclosure, the virtual sensor may set at least one of a heat generation amount of the power conversion device, an initial temperature of the power conversion device, or a temperature of a heat sink as an input variable, and may set at least one of a transient stress of the power conversion device or an initial transient maximum stress of the power conversion device as an output variable.

In the apparatus for protecting a power conversion device according to the present disclosure, the virtual sensor may obtain analytical data by identifying an optimal condition or a key factor based on an experimental result derived from variations in multiple factors affecting the output variable based on design of experiments.

A method of protecting a power conversion device according to an embodiment of the present disclosure may include obtaining measured information, obtaining system variable data, applying the measured information and the system variable data to a reduced-order model stored in a virtual sensor, the reduced-order model being generated in a polynomial form through learning based on accumulated data, comparing a maximum stress of the power conversion device calculated based on an output result from the reduced-order model with a threshold value, and selectively outputting a control signal for prevention of damage to the power conversion device based on a result of comparison.

In the method of protecting a power conversion device according to the present disclosure, the measured information may include data on at least one of an ambient temperature of the power conversion device or a temperature of a coolant.

In the method of protecting a power conversion device according to the present disclosure, the system variable data may include information about at least one of a heat generation amount of the power conversion device or whether to cool the power conversion device.

In the method of protecting a power conversion device according to the present disclosure, the control signal for prevention of damage to the power conversion device may adjust a heat generation amount of the power conversion device through derating.

In the method of protecting a power conversion device according to the present disclosure, the control signal for prevention of damage to the power conversion device may increase heat dissipation through cooling control to prevent application of excessive stress.

A method of protecting a power conversion device according to another embodiment of the present disclosure may include measuring an initial temperature of the power conversion device, estimating an electromagnetic compatibility (EMC) maximum stress of the power conversion device, comparing the magnitude of the EMC maximum stress with a threshold value to determine whether the magnitude of the EMC maximum stress exceeds the threshold value, and adjusting an initial output from the power conversion device based on determining that the magnitude of the EMC maximum stress exceeds the threshold value.

According to an aspect of the present disclosure, an apparatus for protecting a power conversion device is provided. The apparatus may comprise a virtual sensor configured to input sensed data and system variable data to a reduced-order model, generated in a polynomial form through learning based on accumulated data, to determine a maximum stress of the power conversion device, and a controller configured to compare the maximum stress of the power conversion device determined by the virtual sensor with a threshold value and selectively output a control signal for prevention of damage to the power conversion device, based on a result of comparison.

According to an exemplary embodiment, the apparatus may comprise a measured information provider configured to provide the sensed data.

According to an exemplary embodiment, the apparatus may comprise a system information provider configured to provide the system variable data.

According to an exemplary embodiment, the sensed data may comprise data on at least one of an ambient temperature of the power conversion device or a temperature of a coolant.

According to an exemplary embodiment, the system variable data may comprise information about at least one of a heat generation amount of the power conversion device or whether to cool the power conversion device.

According to an exemplary embodiment, the control signal for prevention of damage to the power conversion device may be configured to adjust a heat generation amount of the power conversion device through derating.

According to an exemplary embodiment, the control signal for prevention of damage to the power conversion device may be configured to increase heat dissipation through cooling control to prevent an application of excessive stress.

According to an exemplary embodiment, the reduced-order model may be configured to employ a regression model configured to numerically output a result value for the inputted actually sensed data and the inputted system variable data.

According to an exemplary embodiment, the regression model may comprise any one of an artificial intelligence model, a response surface model, and a polynomial regression model.

According to an exemplary embodiment, the reduced-order model may be configured to receive an initial temperature value and a power value of a predetermined portion of the power conversion device, and output a maximum stress value of the predetermined portion.

According to an exemplary embodiment, the virtual sensor may be configured to set at least one of a heat generation amount of the power conversion device, an initial temperature of the power conversion device, or a temperature of a heat sink as an input variable, and set at least one of a transient stress of the power conversion device or an initial transient maximum stress of the power conversion device as an output variable.

According to an exemplary embodiment, the virtual sensor may be configured to obtain analytical data by identifying an optimal condition or a key factor based on an experimental result derived from variations in multiple factors affecting the output variable based on design of experiments.

According to an aspect of the present disclosure, a method of protecting a power conversion device is provided. The method may comprise applying measured information and system variable data to a reduced-order model stored in a virtual sensor, the reduced-order model being generated in a polynomial form through learning based on accumulated data, and, using a controller, comparing a maximum stress of the power conversion device determined based on an output result from the reduced-order model with a threshold value and selectively outputting a control signal for prevention of damage to the power conversion device, based on a result of comparison.

According to an exemplary embodiment, the method may comprise obtaining the measured information.

According to an exemplary embodiment, the method may comprise obtaining the system variable data.

According to an exemplary embodiment, the measured information may comprise data on at least one of an ambient temperature of the power conversion device or a temperature of a coolant.

According to an exemplary embodiment, the system variable data may comprise information about at least one of a heat generation amount of the power conversion device or whether to cool the power conversion device.

According to an exemplary embodiment, the control signal for prevention of damage to the power conversion device may be configured to adjust a heat generation amount of the power conversion device through derating.

According to an exemplary embodiment, the control signal for prevention of damage to the power conversion device may be configured to increase heat dissipation through cooling control to prevent application of excessive stress.

According to an aspect of the present disclosure, a method is provided. The method may comprise measuring an initial temperature of a power conversion device, estimating an electromagnetic compatibility (EMC) maximum stress of the power conversion device, comparing a magnitude of the EMC maximum stress with a threshold value to determine whether the magnitude of the EMC maximum stress exceeds the threshold value, and adjusting an initial output from the power conversion device when the magnitude of the EMC maximum stress exceeds the threshold value.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The foregoing and other aspects, features, and advantages, as well as the following detailed description of the embodiments, will be better understood when read in conjunction with the accompanying drawings. However, the present disclosure is not intended to be limited to the details shown in the drawings, and various modifications and structural changes may be made therein without departing from the spirit of the present disclosure and within the scope and range of equivalents of the claims. Like reference numbers and designations in the various drawings indicate like elements.

FIG. 1 illustrates a block diagram schematically showing the configuration of a power conversion device protection apparatus, according to an exemplary embodiment of the present disclosure.

FIG. 2 illustrates a flowchart showing a power conversion device protection method, according to an exemplary embodiment of the present disclosure.

FIG. 3 illustrates a view showing an example of data accumulation for construction of a reduced-order model prior to implementation of the apparatus and method for protecting a power conversion device, according to an exemplary embodiment of the present disclosure.

FIG. 4 illustrates a view showing an example of extraction of three-dimensional stress data utilizing two-dimensional temperature and power data according to implementation of the apparatus and method for protecting a power conversion device, according to an exemplary embodiment of the present disclosure.

FIG. 5 illustrates a flowchart showing a method of protecting a power conversion device, according to an exemplary embodiment of the present disclosure.

FIG. 6 illustrates a flowchart showing a method of protecting a power conversion device, according to an exemplary embodiment of the present disclosure.

### DETAILED DESCRIPTION

Various exemplary embodiments will now be described more fully with reference to the accompanying drawings, in which only some exemplary embodiments are shown. Specific structural and functional details disclosed herein are merely representative for the purpose of describing exemplary embodiments. The present disclosure, however, may be embodied in many alternative forms, and should not be construed as being limited to the exemplary embodiments set forth herein.

Accordingly, while exemplary embodiments of the disclosure are capable of being variously modified and taking alternative forms, embodiments thereof are shown by way of example in the drawings and will herein be described in detail. It should be understood, however, that there is no intent to limit the present disclosure to the particular exemplary embodiments disclosed. On the contrary, exemplary embodiments are to cover all modifications, equivalents, and alternatives falling within the scope of the disclosure.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of exemplary embodiments of the present disclosure.

It will be understood that when an element is referred to as being “connected” or “coupled” to another element, it can be directly connected or coupled to the other element, or intervening elements may be present. In contrast, when an element is referred to as being “directly connected” or “directly coupled” to another element, there are no intervening elements present. Other words used to describe the relationship between elements should be interpreted in a like fashion (e.g. “between” versus “directly between,” “adjacent” versus “directly adjacent,” etc.). Similarly, it will be understood that, when an element is referred to as being “disposed on” another element, it may be directly disposed on the surface of the other element or may be disposed above the surface of the other element with a spacing distance therefrom.

The terminology used herein is for the purpose of describing particular embodiments only and is not intended to be limiting of exemplary embodiments of the disclosure. As used herein, the singular forms are intended to include the plural forms as well, unless the context clearly indicates otherwise. It will be further understood that the terms “comprises,” “comprising,” “includes,” and/or “including,” when used herein, specify the presence of stated features, integers, steps, operations, elements, components, or combinations thereof, but do not preclude the presence or addition of one or more other features, integers, steps, operations, elements, components, or combinations thereof.

Unless otherwise defined, all terms used herein, which include technical or scientific terms, have the same meanings as those generally appreciated by those skilled in the art. The terms, such as ones defined in common dictionaries, should be interpreted as having the same meanings as terms in the context of pertinent technology, and should not be interpreted as having ideal or excessively formal meanings unless clearly defined in the specification.

Meanwhile, when a certain embodiment is capable of being realized in a different manner, functions or operations specified in a specific block may be executed in an order different from that shown in a flowchart. For example, two consecutive blocks may be executed simultaneously, or may be executed in the reverse order, depending on the related function or operation.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles. In aspects, a vehicle may comprise an internal combustion engine system as disclosed herein.

Hereinafter, a power conversion device protection apparatus and a power conversion device protection method using the same according to the present disclosure will be described with reference to the accompanying drawings.

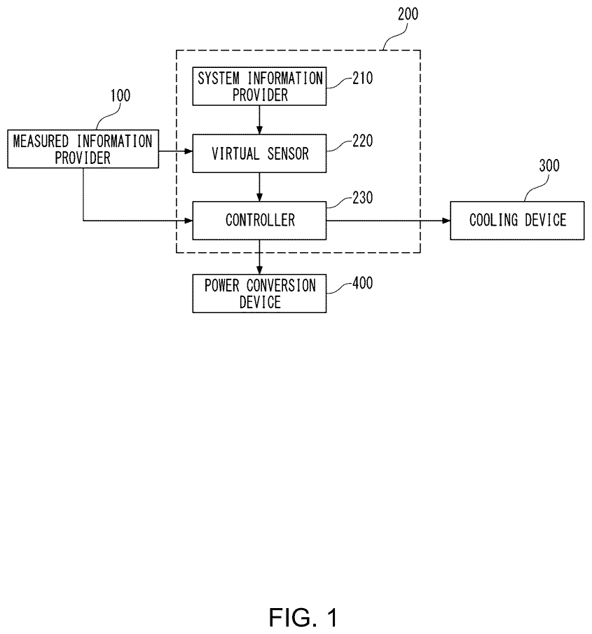

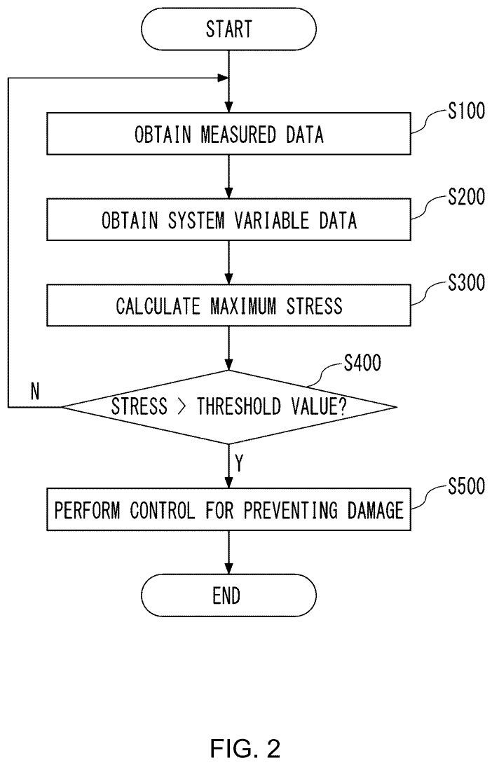

FIG. 1 illustrates a block diagram schematically showing the configuration of a power conversion device protection apparatus, according to an exemplary embodiment of the present disclosure, and FIG. 2 illustrates a flowchart showing a power conversion device protection method, according to an exemplary embodiment of the present disclosure.

The power conversion device described in this specification may represent a component power conversion device mounted in a vehicle, and the vehicle may comprise an internal combustion engine vehicle comprising an engine as a power source, a hybrid vehicle comprising both an engine and an electric motor as power sources, and an electric vehicle comprising an electric motor as a power source.

The power conversion device protection apparatus, according to an exemplary embodiment of the present disclosure may comprise a measured information provider 100 and a power conversion controller 200.

The measured information provider 100 may be configured to provide the power conversion controller 200 with data on at least one actually detected temperature among the ambient temperature of a power conversion device 400 and the temperature of a coolant.

The power conversion controller 200 may comprise a system information provider 210, a virtual sensor 220, and a controller 230. For example, the system information provider 210, the virtual sensor 220, and the controller 230 may represent functions implemented by software executed in a processor.

The measured information provider 100 may be configured to transmit temperature data to the virtual sensor 220 and the controller 230. In the power conversion controller 200 implemented in the form of a processor, the system information provider 210, the virtual sensor 220, and the controller 230 may be implemented in the form of software. However, the measured information provider 100 may be implemented as a hardware sensor of a semiconductor device, which has a temperature detecting function, for example, a thermistor whose resistance value varies depending on changes in temperature.

The virtual sensor 220 may be configured to obtain current temperature information around the power conversion device 400 based on the data provided from the measured information provider 100 (S100).

The system information provider 210 may be configured to provide system control variable data to the virtual sensor 220. The system control variable data may comprise information about at least one of the heat generation amount of the power conversion device 400 or whether to cool the power conversion device 400. That is, when the virtual sensor 220 obtains an external temperature of the power conversion device 400 or a preset target value as an input variable, information about the heat generation amount of the power conversion device for temperature control or whether to cool the power conversion device for temperature adjustment may be included as control variables directly adjustable by the power conversion controller 200. The virtual sensor 220 may be configured to obtain the variable data for control of the system from the system information provider 210 (S200).

The virtual sensor 220 may be configured to store a reduced-order model (ROM), which is generated in a polynomial form through learning based on accumulated data. The reduced-order model, also referred to as a reduced-dimension model, refers to approximating a complex high-order mathematical model or system with a simplified low-order model. This technique reduces the order (dimension) of the system while maintaining the fundamental characteristics (dynamic behavior, stability, and response characteristics) of the system, thereby reducing computational load and enabling faster and more efficient analysis or control.

For example, when the reduced-order model is applied to calculate thermal stress of the power conversion device as in the present disclosure, it is necessary to calculate thermal stress caused by power variation resulting from temperature variation in each part of the power conversion device. In order to calculate the temperature variation in all parts of the power conversion device and resulting power variation, high-order differential equations or highly complex computational formulas may be required.

The reduced-order model may employ various methods. One example is a balanced order reduction method, in which only the most significant states that represent the input and output characteristics of the system are retained, while less influential states are discarded to maintain both stability and accuracy. Another example is a moment-matching method, which preserves the response characteristics within a specific frequency range and is frequently used in large-scale circuit analysis or electromagnetic simulations.

The virtual sensor 220 may be configured to substitute the obtained measured temperature information and variable data required for system control into the reduced-order model. The reduced-order model utilized by the virtual sensor 220 may be configured to employ a regression model that numerically outputs a result value for a given input.

A regression model is a statistical technique used to predict continuous numerical values by mathematically estimating the relationship between independent variables (input, X) and dependent variables (output, Y). For example, when information such as area, location, and the number of rooms is input as independent variables, the house price corresponding thereto is represented numerically. Likewise, when a specific advertising cost is input as an independent variable in a particular region and season, the resulting sales amount is represented as an output value, which is a dependent variable. In the present disclosure, the regression model may be any one of an artificial intelligence model, a response surface model, and a polynomial regression model.

The virtual sensor 220 may be configured to calculate a maximum stress corresponding to the input temperature and power information using the reduced-order model. The maximum stress refers to the largest stress value caused by temperature variations. In general, an object expands or contracts due to changes in temperature. However, when such expansion or contraction is structurally constrained, internal stress is generated. This stress is referred to as thermal stress. Thermal stress is proportional to the elastic modulus, the coefficient of thermal expansion, and the temperature change of the material. The virtual sensor 220 may be configured to set at least one of the heat generation amount of the power conversion device, the initial temperature of the power conversion device, or the temperature of a heat sink as an input variable, and sets at least one of a transient stress of the power conversion device or an initial transient maximum stress of the power conversion device as an output variable. The virtual sensor 220 may be configured to obtain analytical data by identifying an optimal condition or a key factor based on an experimental result derived from variations in multiple factors affecting the output variable based on design of experiments (DOE).

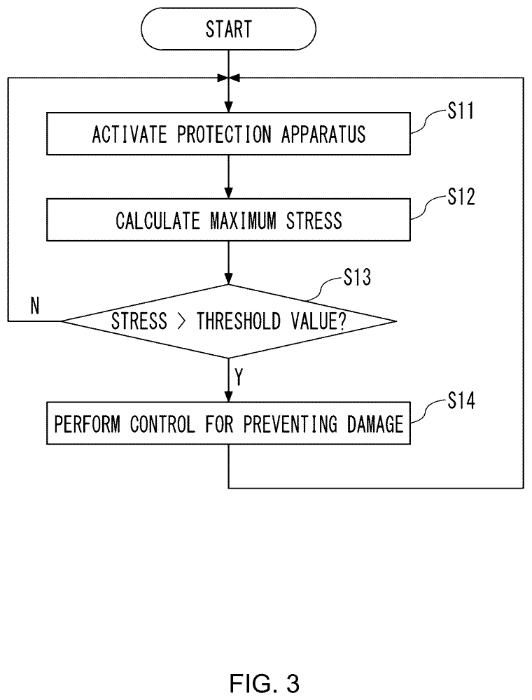

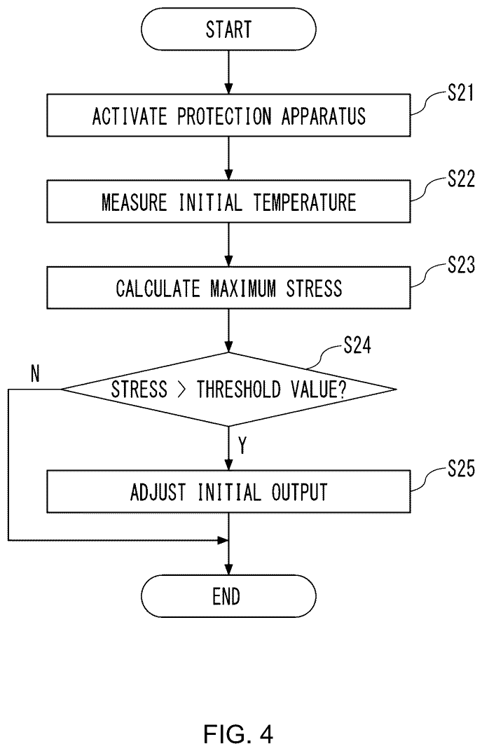

FIG. 3 illustrates a view showing an example of data accumulation for construction of a reduced-order model prior to the implementation of the apparatus and method for protecting a power conversion device, according to an exemplary embodiment of the present disclosure, and FIG. 4 illustrates a view showing an example of extraction of three-dimensional stress data utilizing two-dimensional temperature and power data according to the implementation of the apparatus and method for protecting a power conversion device, according to an exemplary embodiment of the present disclosure.

As shown in FIG. 3, the temperature and the corresponding power at portion “a” of the power conversion device 400 are indicated by a1 to a5. However, this is merely an example. In order to implement the present disclosure, training data may be accumulated not only from portion “a” but also from numerous vulnerable portions of the power conversion device 400.

For example, “a1” indicates that the temperature at portion “a” is below about −40° C. and the power at portion “a” is about 40,000 mW to about 50,000 mW. “a2” indicates that the temperature at portion “a” is about −40° C. to about −20° C. and the power at portion “a” is about 90,000 mW. “a3” indicates that the temperature at portion “a” is about 40° C. and the power at portion “a” is about 70,000 mW to about 80,000 mW. “a4” indicates that the temperature at portion “a” is about 0° C. to about 20° C. and the power at portion “a” is about 20,000 mW to about 30,000 mW. “a5” indicates that the temperature at portion “a” is about 40° C. to about 60° C. and the power at portion “a” is about 10,000 mW to about 20,000 mW.

The virtual sensor 220, which receives the temperature variations and the corresponding power magnitudes as input variables, may be configured to calculate stress based on these inputs, thereby generating three-dimensional data, as shown in FIG. 4. For example, the virtual sensor 220 employs a reduced-order model, which is generated in a polynomial form through learning based on accumulated data rather than through complex computations. Design of experiments (DOE) employing a two-dimensional response surface model is a method in which experiments are performed while systematically varying multiple factors influencing a result and the experimental results are then analyzed to efficiently and scientifically identify an optimal condition or a key factor. For example, a two-dimensional equation used in the reduced-order model, according to an exemplary embodiment of the present disclosure, may be expressed according to Equation 1.

$$Y = - 8.81 {e}^{+ 0} + ( 1.67 {e}^{- 8} ) \times X 1 + ( 1.45 {e}^{- 4} ) \times X 2 + ( 2.31 {e}^{- 5} ) \times X {1}^{2} + ( - 6.28 {e}^{- 7} ) \times X 1 \times X 2 + ( - 1.26 {e}^{- 10} ) \times X {2}^{2} \qquad Equation 1$$

The virtual sensor 220 may be configured to input temperature data and power data as independent variables x1 and x2, respectively, and may be configured to calculate the maximum stress as a dependent variable y. When the temperature data x1 and power data x2 for portion “a” of the power conversion device correspond to “a1” in FIG. 3, the maximum stress corresponding thereto may be indicated by “a1” in FIG. 4. When the temperature data x1 and power data x2 for portion “a” of the power conversion device correspond to “a2” in FIG. 3, the maximum stress corresponding thereto may be indicated by “a2” in FIG. 4. In addition, “a3,” “a4,” and “a5” may also be calculated in the same manner. The virtual sensor 220 may be configured to provide the calculated maximum stress information to the controller 230 (S300).

The controller 230 may be configured to compare the maximum stress value calculated by the virtual sensor 220 with a threshold value. When the magnitude of the currently calculated stress is less than the threshold value, the stress currently applied to a predetermined portion (e.g., a vulnerable portion) of the power conversion device is below the allowable limit. That is, the power conversion device is capable of operating stably. In detail, because the stress caused by temperature variation acts within the elastic range of the power conversion device, the form distorted by temperature variation may be restored to the original state. For example, the magnitude of fatigue applied to the power conversion device is small, and the possibility of damage caused thereby is low. Therefore, because the risk of damage due to stress is low, the system returns to a standby state for initial sensing.

Conversely, the current stress may exceed the threshold having a limit value. That is, the power conversion device may be deformed or damaged due to the stress caused by the current temperature variation. As a result, when the stress exceeds the elastic limit of the power conversion device, permanent imbalance or deformation may occur (S400).

When the maximum stress calculated by the virtual sensor 220 is greater than the threshold value, the controller 230 may be configured to selectively output a control signal for preventing damage to the power conversion device. For example, the control signal for preventing damage to the power conversion device may comprise a method of adjusting the heat generation amount of the power conversion device 400 through derating. Another form of the control signal for preventing damage to the power conversion device may comprise a method of increasing heat dissipation through cooling control using a cooling device 300, thereby preventing application of excessive stress (S500).

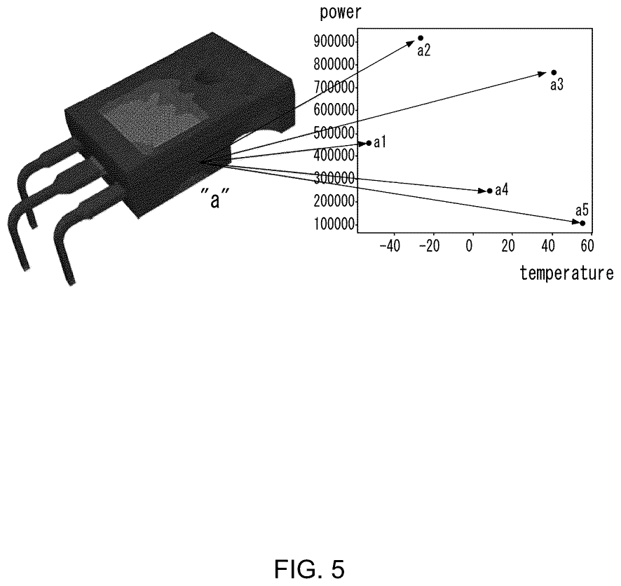

FIG. 5 illustrates a flowchart showing a method of protecting a power conversion device, according to an exemplary embodiment of the present disclosure. The power conversion device protection method, according to an exemplary embodiment of the present disclosure, may be implemented in real time through the power conversion controller 200. That is, when the operation of the power conversion device protection apparatus is activated (S11), the virtual sensor 220 may be configured to receive the ambient temperature of the power conversion device 400 from the hardware temperature sensor 100, and obtain heat generation information from the system information provider 210 to calculate the maximum stress of the power conversion device (S12). The controller 230 may be configured to compare the calculated maximum stress value received from the virtual sensor 220 with a threshold value (S13). When the calculated stress value is less than the threshold value, the operation of the protection apparatus returns to the initial protection operation. When the stress value exceeds the threshold value, the controller 230 transmits a control signal for preventing damage to the power conversion device to the cooling device 300 to increase heat dissipation and adjust the cooling temperature, or transmits the control signal to the power conversion device 400 to adjust the heat generation amount.

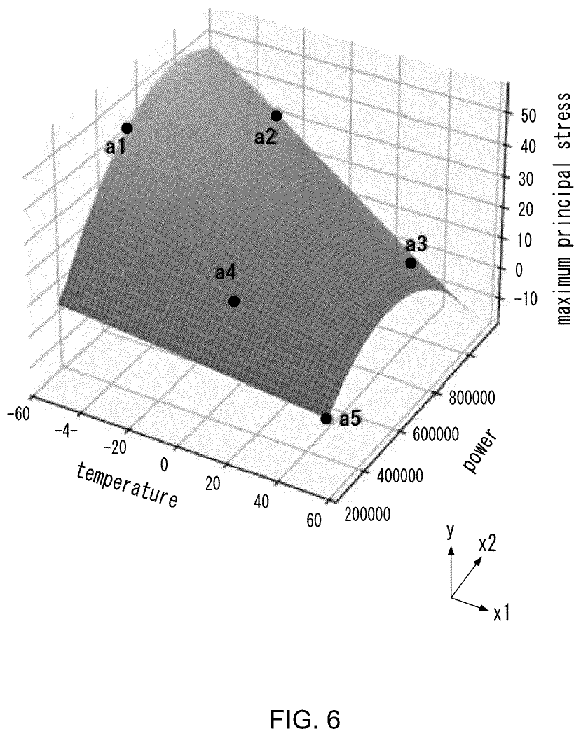

FIG. 6 illustrates a flowchart showing a method of protecting a power conversion device, according to an exemplary embodiment of the present disclosure. The power conversion device protection method, according to an exemplary embodiment of the present disclosure, may control an initial operation of the power conversion device through the power conversion controller 200.

When the operation of the power conversion device protection apparatus is activated (S21), the virtual sensor 220 may be configured to receive the initial temperature around the power conversion device 400 from the hardware temperature sensor 100 (S22), obtain heat generation information of the power conversion device from the system information provider 210, and calculate a maximum stress of the power conversion device (S23). The controller 230 may be configured to compare the calculated maximum stress value received from the virtual sensor 220 with a threshold value (S24). When the calculated stress value is less than the threshold value, the controller 230 determines that there is no problem in the initial operation of the power conversion device. When the stress value exceeds the threshold value, the controller 230 adjusts an initial output from the power conversion device 400 to prevent damage to the power conversion device (S25).

The controller 230 may be configured to compare the stress estimated or calculated by the virtual sensor 220 with the EMC material strength or bonding strength. The controller 230 may be configured to use the comparison result to control cooling or an output in real time so that excessive stress is not applied, or may derive an initial output and apply the same to the control operation.

The apparatus and method for protecting a power conversion device according to the present disclosure may estimate thermal stress applied to a power conversion device in a vehicle using only virtual sensor software without mounting a hardware sensor. Based on the estimated thermal stress, a control signal for preventing damage to a vulnerable portion of the power conversion device may be output, and may be utilized to monitor the state of the power conversion device and to predict failure thereof.

As is apparent from the above description, according to the apparatus and method for protecting a power conversion device according to the present disclosure, thermal stress applied to a power conversion device in a vehicle may be estimated solely through virtual sensor software without the need for any hardware sensors. Based on the estimated thermal stress, a control signal may be generated to protect the power conversion device from damage, which may also be used for device condition monitoring and failure prediction.

Although the exemplary embodiments of the present disclosure have been disclosed for illustrative purposes, those skilled in the art will appreciate that various modifications, additions and substitutions are possible, without departing from the scope and spirit of the disclosure as disclosed in the accompanying claims.

What is claimed is:

1. An apparatus for protecting a power conversion device, the apparatus comprising:
a virtual sensor configured to input sensed data and system variable data to a reduced-order model, generated in a polynomial form through learning based on accumulated data, to determine a maximum stress of the power conversion device; and
a controller configured to:
compare the maximum stress of the power conversion device determined by the virtual sensor with a threshold value; and
selectively output a control signal for prevention of damage to the power conversion device, based on a result of comparison.

2. The apparatus according to claim 1, further comprising a measured information provider configured to provide the sensed data.

3. The apparatus according to claim 2, further comprising a system information provider configured to provide the system variable data.

4. The apparatus according to claim 3, wherein the sensed data comprises data on at least one of an ambient temperature of the power conversion device or a temperature of a coolant.

5. The apparatus according to claim 3, wherein the system variable data comprises information about at least one of a heat generation amount of the power conversion device or whether to cool the power conversion device.

6. The apparatus according to claim 3, wherein the control signal for prevention of damage to the power conversion device is configured to adjust a heat generation amount of the power conversion device through derating.

7. The apparatus according to claim 3, wherein the control signal for prevention of damage to the power conversion device is configured to increase heat dissipation through cooling control to prevent an application of excessive stress.

8. The apparatus according to claim 3, wherein the reduced-order model is configured to employ a regression model configured to numerically output a result value for the inputted actually sensed data and the inputted system variable data.

9. The apparatus according to claim 8, wherein the regression model comprises any one of an artificial intelligence model, a response surface model, and a polynomial regression model.

10. The apparatus according to claim 8, wherein the reduced-order model is configured to:
receive an initial temperature value and a power value of a predetermined portion of the power conversion device; and
output a maximum stress value of the predetermined portion.

11. The apparatus according to claim 11, wherein the virtual sensor is configured to:
set at least one of a heat generation amount of the power conversion device, an initial temperature of the power conversion device, or a temperature of a heat sink as an input variable; and
set at least one of a transient stress of the power conversion device or an initial transient maximum stress of the power conversion device as an output variable.

12. The apparatus according to claim 11, wherein the virtual sensor is configured to obtain analytical data by identifying an optimal condition or a key factor based on an experimental result derived from variations in multiple factors affecting the output variable based on design of experiments.

13. A method of protecting a power conversion device, the method comprising:
applying measured information and system variable data to a reduced-order model stored in a virtual sensor, the reduced-order model being generated in a polynomial form through learning based on accumulated data; and
using a controller:
comparing a maximum stress of the power conversion device determined based on an output result from the reduced-order model with a threshold value; and
selectively outputting a control signal for prevention of damage to the power conversion device, based on a result of comparison.

14. The method according to claim 13, further comprising obtaining the measured information.

15. The method according to claim 14, further comprising obtaining the system variable data.

16. The method according to claim 14, wherein the measured information comprises data on at least one of an ambient temperature of the power conversion device or a temperature of a coolant.

17. The method according to claim 14, wherein the system variable data comprises information about at least one of a heat generation amount of the power conversion device or whether to cool the power conversion device.

18. The method according to claim 14, wherein the control signal for prevention of damage to the power conversion device is configured to adjust a heat generation amount of the power conversion device through derating.

19. The method according to claim 14, wherein the control signal for prevention of damage to the power conversion device is configured to increase heat dissipation through cooling control to prevent application of excessive stress.

20. A method, comprising:
measuring an initial temperature of a power conversion device;
estimating an electromagnetic compatibility (EMC) maximum stress of the power conversion device;
comparing a magnitude of the EMC maximum stress with a threshold value to determine whether the magnitude of the EMC maximum stress exceeds the threshold value; and
adjusting an initial output from the power conversion device when the magnitude of the EMC maximum stress exceeds the threshold value.
